(19) United States
(12) Patent Application Publication
(10) Pub. No.: US 2025/0272458 A1
(43) Pub. Date: Aug. 28, 2025

(54) ACOUSTIC ANNOTATION TRAINING METHOD, SYSTEM, AND DEVICE APPLIED TO PHYSICAL CHANGE PHENOMENA

(71) Applicant: CHIA-HUNG CHEN, New Taipei (TW)

(72) Inventors: CHIA-HUNG CHEN, New Taipei (TW); CHIA-CHI SU, New Taipei (TW); JIAN-LONG SU, New Taipei (TW); RONG-SHEN LIN, New Taipei (TW); CHING-YU LI, New Taipei (TW)

(21) Appl. No.: 19/065,240

(22) Filed: Feb. 27, 2025

Related U.S. Application Data
(60) Provisional application No. 63/559,167, filed on Feb. 28, 2024.

(51) Int. Cl. G06F 30/27; G06V 10/774; G06V 20/70

(52) U.S. Cl. CPC G06F 30/27; G06V 10/774; G06V 20/70

(57) ABSTRACT

The present invention provides an acoustic annotation training method, system, and device applied to physical change phenomena. The steps of the acoustic annotation training method include: acquiring a physical change phenomenon by an acquisition unit; generating and transmitting a corresponding acoustic signal by a transmitting portion based on the physical change phenomenon; receiving the acoustic signal and performing computational analysis based on changes in the acoustic signal by a receiving portion to generate corresponding physical change information; and receiving the physical change information and annotating the physical change phenomenon by a computing processing unit to perform multimodal computational analysis, thereby producing an analysis result. By executing this method through the system/device, automated annotation is achieved, enabling the establishment of highly accurate multimodal analysis.

### CROSS-REFERENCE TO RELATED APPLICATION

This application claims the benefit of provisional application Ser. No. 63/559,167, filed Feb. 28, 2024. The disclosure of the above application is incorporated herein in its entirety by reference.

### FIELD OF THE INVENTION

An annotation training method, system, and device, particularly relating to an acoustic annotation training method, system, and device applied to physical change phenomena.

### BACKGROUND OF THE INVENTION

Although image training is relatively mature in existing technologies, it still has its limitations, especially being prone to data bias. Particularly in physical change phenomena, different lighting and angles may lead to visual errors. For example, boiling water at 100° C. in an image may appear similar to freezing under different lighting and angles, resulting in inaccurate training outcomes. Additionally, physical phenomena such as changes in airflow rate, humidity, light, and fluctuations may exhibit very subtle differences in images, significantly increasing the difficulty of image training.

To this end, the present invention provides an acoustic annotation training method, system, and device applied to physical change phenomena, which automatically converts and performs annotations based on changes in acoustic signals. This not only significantly improves the accuracy of analysis results but also effectively addresses the issue of traditional difficulties in learning and training physical phenomena changes in images.

### SUMMARY OF THE INVENTION

The primary objective of the present invention is to provide a method for training acoustic annotations applied to physical change phenomena, and the method conveys information about physical changes through acoustic signals, thereby enabling automatic annotation training for such phenomena and establishing highly accurate analysis results.

Another objective of the present invention is to provide a acoustic annotation training system applied to physical change phenomena, and the system generates and emits acoustic signals through a conversion unit based on physical change phenomena, thereby transmitting the physical change information. This allows the computing processing unit to annotate and train corresponding physical change phenomena through this physical change information, achieving automated annotation.

Another objective of the present invention is to provide a acoustic annotation training device applied to physical change phenomena. A detection device transmits physical change phenomena through acoustic signals, enabling a computing device to perform subsequent annotation and training to obtain highly accurate analysis results.

To achieve the aforementioned objectives, an embodiment of the present invention discloses a acoustic annotation training method applied to physical change phenomena, comprising steps of: acquiring a physical change phenomenon using an acquisition unit; generating and transmitting a corresponding acoustic signal based on the physical change phenomenon by a transmitting portion; receiving the acoustic signal and performing computational analysis based on changes in the acoustic signal by a receiving portion to generate corresponding physical change information; and receiving the physical change information and annotating the physical change phenomenon by a computing processing unit to perform multimodal computational analysis, thereby producing an analysis result.

In a preferred embodiment, in the step where a computing processing unit annotates the physical change phenomenon based on the physical change information to perform multimodal computation analysis and generate an analysis result, the computing processing unit receives and processes the physical change information to generate a corresponding semantic information, thereby enabling the computing processing unit to annotate the physical change phenomenon based on the semantic information.

In a preferred embodiment, the type of the acquired physical change phenomenon is selected from detected electronic signals, images, audio-video, voice, text, or any combination of two or more thereof.

In a preferred embodiment, the physical change phenomenon is selected from spatial position change, temperature change, elastic change, electromagnetic change, optical change, wave change, vibration change, mass change, airflow rate change, humidity change, or a combination of any two or more thereof.

To achieve the aforementioned another objective, an embodiment of the present invention discloses a acoustic annotation training system applied to physical change phenomena, comprising: an acquisition unit for acquiring a physical change phenomenon; a conversion unit, including a transmitting portion and a receiving portion, wherein the transmitting portion is configured to generate and transmit a corresponding acoustic signal based on the physical change phenomenon, and the receiving portion is configured to receive and perform computational analysis based on changes in the acoustic signal, and generating a corresponding physical change information; and a computing processing unit, respectively signal-connected to the capturing unit and the conversion unit, being configured to receive and annotate the physical change phenomenon based on the physical change information, and to perform multimodal computational analysis to produce an analysis result.

In a preferred embodiment, the acquisition unit is selected from an image acquisition device, a voice acquisition device, an input device, a sensing device, or a combination of any two of the above.

To achieve the aforementioned further objective, an embodiment of the present invention discloses a acoustic annotation training device applied to physical change phenomena, comprising: a detection device configured to generate and emit an acoustic signal based on a physical change phenomenon; and a computing device, signal-connected to the detection device, configured to receive and perform computational analysis based on changes in the acoustic signal, generate corresponding physical change information, and annotate the physical change phenomenon based on the physical change information to perform multimodal computational analysis, thereby producing an analysis result.

In a preferred embodiment, the detection device includes a sensing device for detecting the physical change phenomenon and generating the physical change information.

To achieve the aforementioned further objective, an embodiment of the present invention discloses an intelligent automation system, comprising: an automation device; a detection device, signal-connected to the automation device, for acquiring image information, and generating and transmitting a corresponding acoustic signal based on a physical change phenomenon in the image information; a computing device, signal-connected to the detection device, being configured to receive and perform computational analysis based on changes in the acoustic signal, generating a corresponding physical change information, and annotating the image information based on the physical change information to perform multimodal computational analysis, thereby producing an analysis result; and a decision-making device, signal-connected to the automation device and the computing device respectively, being configured to conduct a prediction based on the analysis result and output a decision information, thereby enabling the automation device to operate according to the decision information.

In a preferred embodiment, the automation device is selected from a robotic arm, a self-propelled device, a drone, or a robot.

The beneficial effect of the present invention lies in automated annotation training, thereby establishing highly accurate analysis results and improving the accuracy of prediction outcomes.

### BRIEF DESCRIPTION OF THE DRAWINGS

FIG. 1: flowchart of a method according to an embodiment of the present invention;

FIG. 2A: schematic diagram of a system according to an embodiment of the present invention;

FIG. 2B: schematic diagram of the operation of a system according to an embodiment of the present invention;

FIG. 3A: block diagram of a sound wave training device according to an embodiment of the present invention;

FIG. 3B: block diagram of an intelligent automation system according to an embodiment of the present invention;

FIG. 4A: diagram of received acoustic signals according to an embodiment of the present invention;

FIG. 4B: physical change information of subject A (vertical direction) according to an embodiment of the present invention; and

FIG. 4C: physical change information of subject A (horizontal direction) according to an embodiment of the present invention.

### DETAILED DESCRIPTION OF THE INVENTION

In order to make the above and/or other objectives, effects, and features of the present invention more apparent and easier to understand, preferred embodiments are specifically described below in detail:

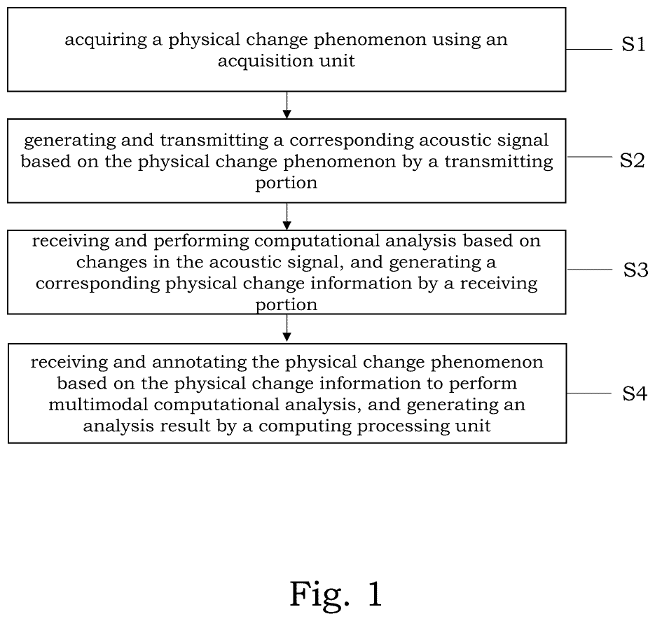

Please refer to FIG. 1, which is a flowchart of a method according to an embodiment of the present invention. As shown in the figure, the steps of a method for training acoustic annotation applied to physical change phenomena according to an embodiment of the present invention are as follows:

Step S1: acquiring a physical change phenomenon using an acquisition unit;

Step S2: generating and transmitting a corresponding acoustic signal based on the physical change phenomenon by a transmitting portion;

Step S3: receiving and performing computational analysis based on changes in the acoustic signal, and generating a corresponding physical change information by a receiving portion; and

Step S4: receiving and annotating the physical change phenomenon based on the physical change information to perform multimodal computational analysis, and generating an analysis result by a computing processing unit.

As shown in step S1, the acquisition unit 1 obtains a physical change phenomenon. In one embodiment, the type of the obtained physical change phenomenon is selected from detected electronic signals, images, audio-video, voice, text, or any combination of two or more thereof. For example, it can be the physical change phenomenon obtained from an image, or it can also be the physical change phenomenon directly presented through electronic signals detected by a sensing unit, but it is not limited to this.

In one embodiment, the physical change phenomenon is selected from the group consisting of spatial position change, temperature change, elastic change, electromagnetic change, optical change, wave change, vibration change, mass change, airflow rate change, humidity change, or a combination of any two or more thereof, but is not limited thereto.

For example, the so-called physical change phenomenon could be a change in temperature, such as the process of boiling water or combustion, or it could be a change in the spatial position of a person/subject/animal, such as the movement of a person/animal in space, the operation of a robotic arm/robot, or the movement of a vehicle, or it could be a spring pulling process, or it could be a change in light in the environment, or a change in sound in the environment, or a change in airflow rate/humidity/temperature in the environment, or a change in vibration of machinery or other subjects, or the fluctuation process of tides. Moreover, the physical change phenomenon can be one or multiple, for example: simultaneous movement of people/subjects/animals in space, temperature changes in space, light changes, and sound changes in the image, but not limited to these.

As shown in step S2, the transmitting portion T1 can generate and transmit corresponding acoustic signals based on the aforementioned physical change phenomena. In one embodiment, the transmitting portion T1 may be selected from an acoustic generating device, but is not limited thereto, as long as it is a device with a speaker, but not limited to this. The frequency range of the acoustic signal can be between 20 Hz and 2 MHz.

In one embodiment, when there are multiple physical change phenomena, they can be transmitted through acoustic signals of different frequencies. For example: human movement changes can be selected from an 18 kHz acoustic signal, cat movement changes can be selected from a 19 kHz acoustic signal, vehicle movement changes can be selected from a 20 kHz acoustic signal, dog movement changes can be selected from a 21 kHz acoustic signal, airflow rate changes can be selected from a 22 kHz acoustic signal, and temperature changes can be selected from a 23 kHz acoustic signal, but are not limited to these.

As shown in step S3, the receiving portion T2 receives the acoustic signal transmitted in the previous step. Based on the changes in the acoustic signal, computational analysis is performed to generate corresponding physical change information. In one embodiment, the receiving portion T2 can be selected from devices such as smartphone, tablet, laptop, personal computer, television, or server, and can also be from headphones as long as the device is equipped with a microphone, but is not limited to these. Among them, the corresponding physical change information can be further analyzed through the intensity changes of acoustic signals at different frequencies. For example, the intensity changes of the acoustic signal can be used to analyze the distance value between the transmitting portion T1 and the receiving portion T2, thereby analyzing the user's movement status. Alternatively, an algorithm can be used to analyze the corresponding temperature value based on the intensity changes of the acoustic signal, or other similar analysis methods.

In one embodiment, the intensity variation of the acoustic signal can be determined based on a Fast Fourier Transform (FFT) operation, where the intensity decreases with increasing distance and, conversely, increases with decreasing distance. This allows the variation in distance between the transmitting portion T1 and the receiving portion T2 to be inferred from the intensity changes. Furthermore, frequency shift information can be calculated using the Doppler effect to generate corresponding acceleration, thereby obtaining the direction of velocity and the rate of change in magnitude, but not limited to this.

As shown in step S4, the computing processing unit 2 can perform multimodal computation analysis based on the physical change information annotated on the physical change phenomenon, thereby generating analysis results. For example, when the form of the physical change phenomenon is audio-visual content of a person cooking, the process of the person/spatula displacement and the process of temperature change in the pot can be split into several images one by one, and each displacement/temperature change can be annotated on the corresponding image. In this way, the physical change phenomenon in the images can be automatically annotated on the corresponding images, achieving more accurate predictions, but not limited to this.

In one embodiment, the generated physical change information can be converted by the computing processing unit 2 to generate corresponding semantic information in the first place. For example, when the physical change information is distance change and acceleration, the numerical changes in distance and acceleration can be converted into text. For instance, the text describes how the position of subject A changes (moving from position A to position B), how the speed changes (the distance subject A moves per second increases from a certain value to another), and how the direction changes (moving horizontally forward from position A to position B). Alternatively, when the physical change information is temperature change, the numerical changes in temperature can be converted into text, such as a temperature value of 100 degrees. Moreover, when a specific temperature value is reached, the specific phenomenon can be described in text, for example: boiling state, but not limited to this.

In one embodiment, multimodal computation analysis includes, but is not limited to, data fusion analysis computation, multimodal learning, and matching analysis computation. Multimodal computation analysis can combine different types of data by performing feature extraction on each type of data separately, fusing these features, and enabling matching the features of different types of data, thereby improving the accuracy of the model. Preferably, ViT (Vision Transformer) can be used as a vision encoder to extract image features with physical change phenomena, and a text encoder can be used to match the physical change information with the image features exhibiting physical change phenomena, thereby generating analysis results, but not limited to this.

In one embodiment, after the analysis results are established, corresponding prediction results can be generated through images/videos/audio/text based on the analysis results. For example, it is possible to predict changes in temperature values, distance values, or other physical phenomena through videos, or generate corresponding prediction results based on descriptions of physical changes in text/audio which may be corresponding images/videos, but are not limited to this.

To verify the beneficial effects of the present invention, training and prediction were conducted based on various physical phenomena changes, as explained below:

Taking the scenario of water heating as an example of physical phenomenon changes, data from four groups were captured by recording video and converting it into images. Model 1 adopts the acoustic annotation training method of the present invention as image annotation and is trained with a multimodal model; Model 2 uses the predicted temperature values provided by the visual model as image annotation and is trained with a multimodal model; Model 3 uses the actual measured temperature as image annotation and is trained with a multimodal model; Model 4 manually groups images based on temperature ranges and uses these grouped images as the training set for the visual model. Among these four Models, although Model 4 achieves high accuracy, the AI vision model results cannot adapt well to different environmental backgrounds and require significant human intervention in dataset preparation. Similarly, Model 3 demands concurrent integration of temperature information with image timing data, necessitating substantial human involvement and verification to prevent misjudgments. On the other hand, Model 2 utilizes current AI visual model preprocessing, which is faster but lacks effective precision. In contrast, Model 1 captures video alongside audio files, enabling immediate temperature labeling for images at specific time points through coding with minimal data preprocessing or labeling effort. As evidenced in the table below, this acoustic-assisted image labeling of temperature information demonstrates significant potential.

The training results are shown in Table 1:

| Training method | Model 1 | Model 2 | Model 3 | Model 4 |
|---|---|---|---|---|
| Total prediction | 420 | 420 | 420 | 420 |
| numbers | | | | |
| Prediction correct | 279 | 93 | 341 | 390 |
| Prediction failed | 141 | 327 | 79 | 30 |
| accuracy | 66.43% | 22.14% | 81.19% | 92.86% |
| Cost of pre- | Low | Low | High | Extremely |
| training data | | | | high |
| labeling | | | | |

Taking the dropping of a sphere as an example of physical phenomenon change, the actual total free-fall distance of the sphere is 1.65 meters. In this case, the acoustic annotation training method of the present invention utilizes the Doppler effect to calculate the acceleration based on sound frequency shifts, providing training for image annotation. The calculation of sound wave frequency shifts involves determining the acceleration from the final sound wave frequency shift, thereby deriving the distance traveled and maximum speed. For inertial measurement unit calculations, data from inertia measure units (IMUs) obtained during the experiment is used to calculate the actual distance traveled and maximum speed.

The predicted free-fall movement distance is as shown in Table 2:

| | | Deviation rate % | |
|---|---|---|---|
| | Free fall | ((Actual distance − | Maximum |
| | travel | Predicted distance)/ | speed in |
| | distance | Actual distance) * | free fall |
| Prediction method | (m) | 100%) | (m/s) |
| Actual measurement | 1.65 | 0 | 5.69 |
| | | | (h = 1/2gt |
| | | | Theoretical |
| | | | value) |
| Sound wave | 1.54 | 6.67% | 5.28 |
| frequency shift | | | |
| calculation with | | | |
| Doppler Effect | | | |
| Inertial measurement | 1.40 | 15.15% | 4.92 |
| unit calculation | | | |
| The acoustic | 1.42 | 13.93% | 4.90 |
| annotation training | | | |
| method of present | | | |
| invention | | | |

All data is calculated using the last photo captured before free fall impacts the ground, in conjunction with ultrasonic frequency shift, inertial measurement units (IMUs), and the acoustic annotation training method of present invention. Ultrasonic frequency shift provides the most accurate distance and velocity calculations in real-world conditions, and image recognition models trained after acoustic annotation is enabled to predict the movement distance and speed of subjects according to the analysis results. Moreover, acoustic frequency shift enables precise calculation of gravitational acceleration for real free-fall motion under different volumes and air resistance conditions. The method of the present invention offers convenient data preprocessing and labeling, significantly improving AI training efficiency, model iteration speed, and algorithm optimization potential.

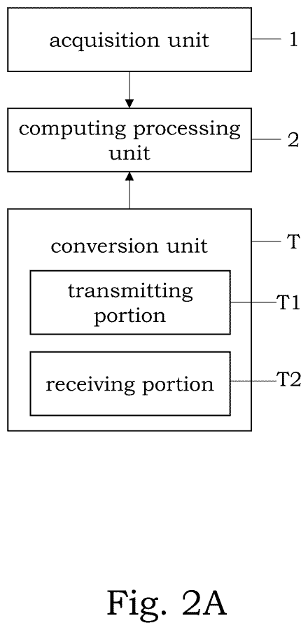

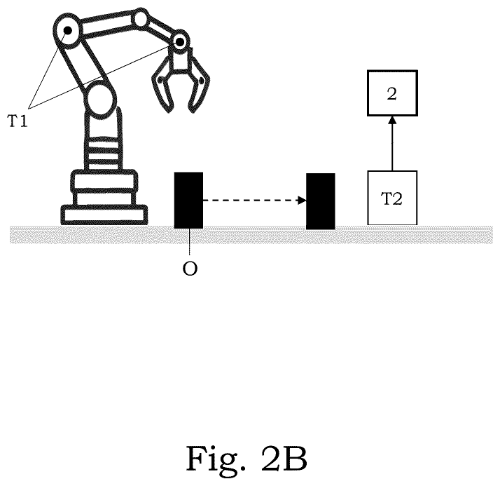

Please refer to FIG. 2A, which is a schematic diagram of a system according to an embodiment of the present invention. As shown in the figure, an embodiment of the present invention provides a acoustic annotation training system applied to physical change phenomena, which includes: an acquisition unit 1, a conversion unit T, and a computing processing unit 2. The computing processing unit 2 is signal-connected to the acquisition unit 1 and the conversion unit T, respectively, and is described in detail as follows:

The acquisition unit 1 is used to obtain physical change phenomena, which can be presented through images/audio/video/text, or through a series of detected electronic signals, but not limited to these. In one embodiment, the acquisition unit 1 includes, but is not limited to, image capture device, voice capture device, input device, sensing device, or any combination of the above can be configured as needed. When the acquisition unit 1 is selected as an image acquisition device, it captures image information and extracts physical change phenomena from the image information.

The conversion unit T includes a transmitting portion T1 and a receiving portion T2. Thus, the transmitting portion T1 generates and transmits a corresponding acoustic wave signal based on physical change phenomena. The acoustic wave signal can range from 20 Hz to 2 MHz. Namely, the transmitted acoustic wave signal can be either an audible signal or an ultrasonic signal. The receiving portion T2 receives this acoustic wave signal, and the changes in the acoustic wave signal received by the receiving portion T2 are computationally analyzed to generate corresponding physical change information, though this is not limited to such.

In one embodiment, the variation of the acoustic signal can be obtained through the intensity/frequency/time variation of the corresponding received acoustic signal. In other words, when a physical phenomenon changes, a specific intensity/frequency/time acoustic signal can be transmitted by the transmitting portion T1 and received by the receiving portion T2. As a result, the intensity/frequency/time of the received acoustic signal will vary correspondingly with the physical phenomenon, thereby generating corresponding physical variation information.

The computing processing unit 2 annotates the corresponding physical change phenomenon based on the received physical change information, thereby performing multimodal computational analysis to generate its analysis result. This analysis result can be used to predict the corresponding physical change phenomenon.

In one embodiment, the computing processing unit 2 may further include a semantic conversion unit configured to process the physical change information to generate corresponding semantic information, thereby enabling the computing processing unit 2 to annotate physical change phenomena based on the semantic information and perform multimodal computational analysis accordingly, but not limited to this.

In one embodiment, please refer to FIG. 2B, which is a schematic diagram of the system operation according to an embodiment of the present invention. As shown in the figure, taking the operation process of a robotic arm as an example, the operation process of the robotic arm moving the subject O from the left side to the right side can be obtained through the acquisition unit 1. At the same time, the transmitting portion T1 emits corresponding acoustic signals based on the operating state of the robotic arm, and the receiving portion T2 receives the corresponding acoustic signals in real time, and generates corresponding physical change information, which may include but is not limited to the spatial position changes of the robotic arm during operation and the sounds produced by the robotic arm during operation.

At this point, the computing processing unit 2 can annotate the corresponding physical change phenomena based on the physical change information, thereby performing subsequent multimodal computational analysis to generate corresponding analysis results. These analysis results may include the overall operating state of the robotic arm, which can be used to detect abnormal movements, abnormal noises, and other results of the robotic arm in the future, or as actual monitoring of the robotic arm's movements. For example, it can determine whether the directional rotation, rotary motion, or linear motion is correct, or whether there are other abnormal states.

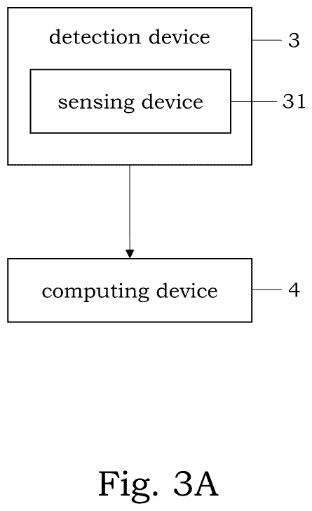

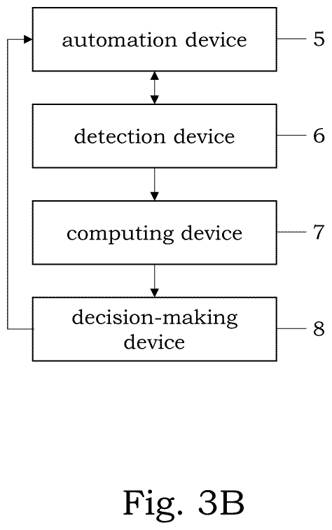

Please refer to FIG. 3A, which is a block diagram of an acoustic annotation training device according to an embodiment of the present invention. As shown in the figure, the acoustic annotation training device applied to physical change phenomena according to an embodiment of the present invention includes: a detection device 3 and a computing device 4, wherein the detection device 3 is signal-connected to the computing device 4, and the details are described as follows:

The detection device 3 is used to generate and transmit acoustic signals based on physical change phenomena. In one embodiment, the detection device 3 includes, but is not limited to, a sensing device 31. The detection device may not be equipped with the sensing device 31. Namely, it can directly generate and transmit corresponding acoustic signals based on physical change phenomena. Alternatively, the sensing device 3 can detect physical change phenomena, generate corresponding physical change information, and use the physical change information to generate and transmit corresponding acoustic signals. In other words, the transmitted acoustic signal itself contains physical change information. The frequency range of the acoustic signal can be between 20 Hz and 2 MHz, but is not limited to this range.

In one embodiment, the so-called physical change phenomenon may be selected from spatial position change, temperature change, elastic change, electromagnetic change, optical change, wave change, vibration change, mass change, airflow rate change, humidity change, or a combination of any two or more thereof, but is not limited thereto.

The computing device 4 is used to receive the acoustic signal emitted by the detection device 3, thereby performing computational analysis based on the changes in the acoustic signal to generate corresponding physical change information. Thus, multimodal computational analysis is performed according to the physical change information annotation corresponds to the physical change phenomenon so as to generate analysis results. In one embodiment, the computing device 4 may include an input device configured to receive the acoustic signal emitted by the detection device 3. The input device can be one or more microphones, but is not limited to this.

In one embodiment, it can also be used as a training device in intelligent automation equipment. For example, traditional intelligent robots or other self-propelled devices are equipped with maps and their positioning systems. However, they still cannot quickly grasp changes in relative spatial positions when recognizing the environment. Please refer to FIG. 3B, which is a block diagram of an intelligent automation system according to an embodiment of the present invention. As shown in the figure, an intelligent automation system includes: an automation device 5, a detection device 6, a computing device 7, and a decision-making device 8. The automation device 5 is signal-connected to the detection device 6, the computing device 7 is signal-connected to the detection device 6, and the decision-making device 8 is signal-connected to both the automation device 5 and the computing device 7. The details are as follows:

The automation equipment 5 is a machine or system used to automatically perform specific tasks. In one embodiment, the automation equipment is selected from robotic arms, self-propelled devices, drones, or robots, but is not limited to these, as long as it is equipment capable of automatically executing specific tasks based on detection/recognition results.

The implementation of the detection device 6 and the computing device 7 is the same as the previous embodiment, so further details are omitted here for brevity.

The decision-making device 8 is used to predict and output decision-making information based on the analysis results generated by the computing device 7, thereby enabling the automation device 5 to operate according to the decision-making information. In other words, the intelligent automation system of the present invention transmits changes in its physical phenomena (such as spatial position changes, temperature changes, etc.) in real-time through acoustic signals. This allows for rapid positioning and subsequent movement or analysis of the intelligent automation system. As a result, it avoids the need for traditional intelligent robots or other self-propelled devices to spend a significant amount of time updating all information about a new environment. At the meantime, it can more quickly adapt to environmental changes in various locations, but is not limited to this.

To more clearly illustrate the embodiments of the present invention, examples are as below:

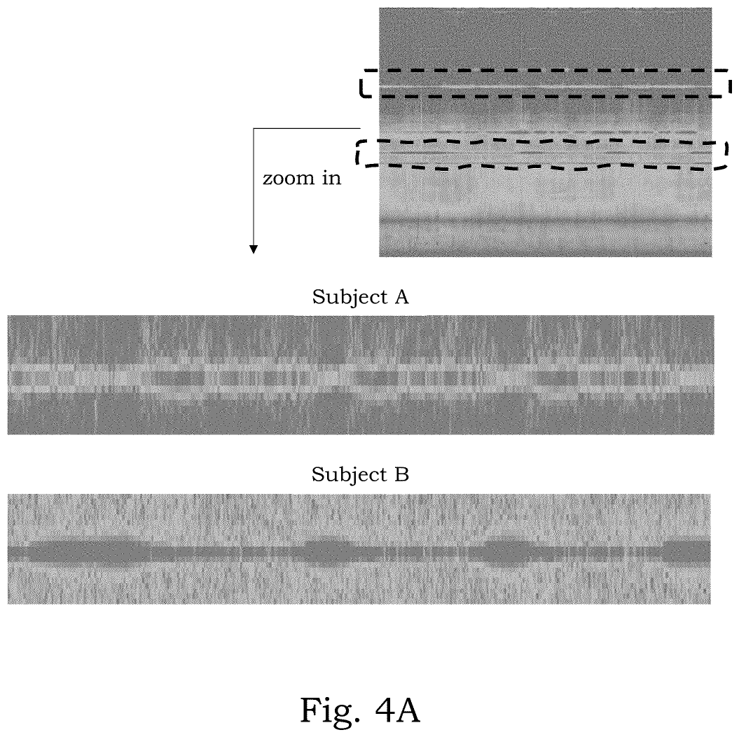

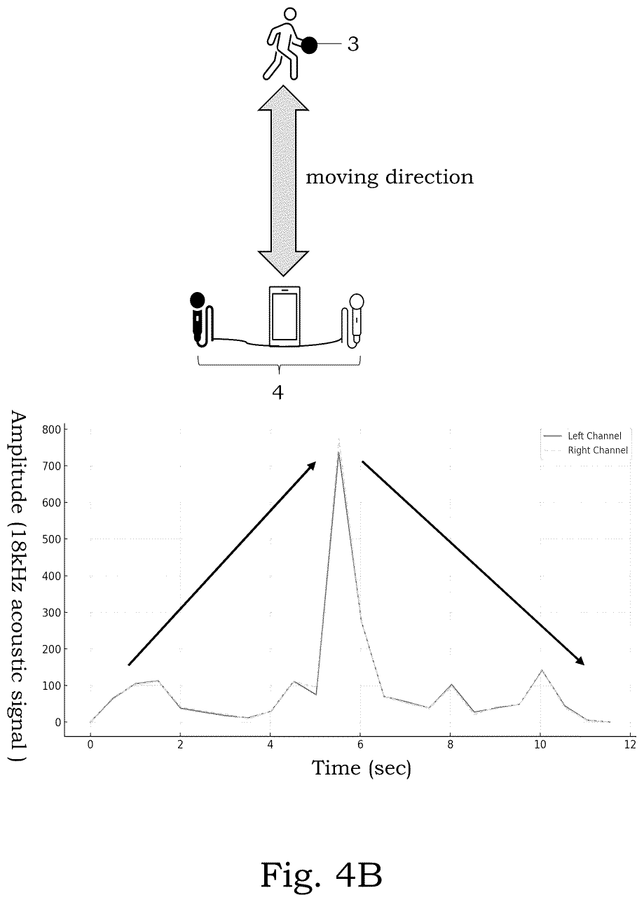

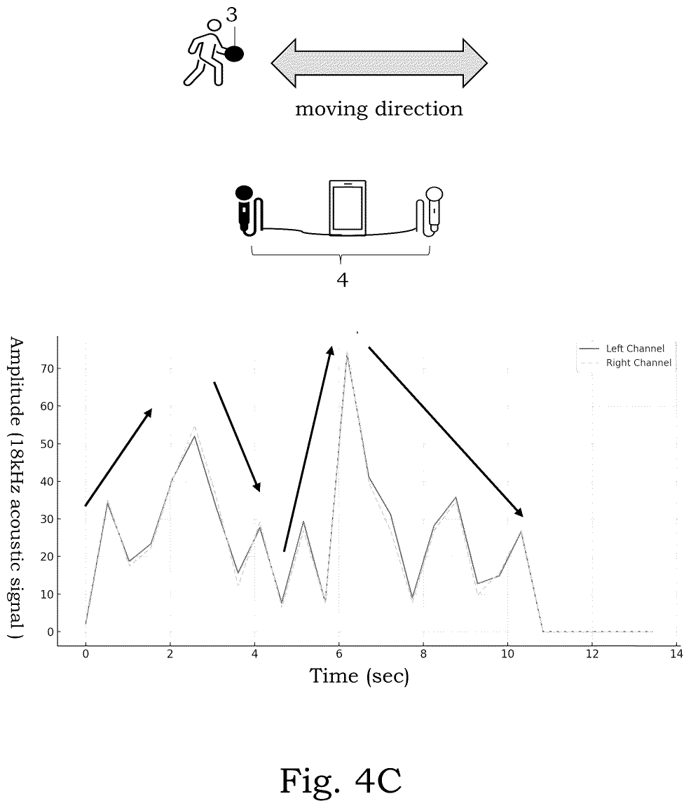

In one embodiment, please refer to FIG. 4A, which is a diagram of received acoustic signals according to an embodiment of the present invention. As shown in the figure, the first implementation involves using an image capture device to acquire images of different subjects as their spatial positions change. Here, subject A is equipped with an acoustic generating device with a frequency of 18 kHz, and subject B is equipped with an acoustic generating device with a frequency of 20 kHz. The spatial changes of subjects A and B can be detected by the corresponding acoustic signals emitted by the acoustic generating devices, allowing the computing device 4 to calculate the corresponding spatial positions and their motion states based on the intensity changes of the received acoustic signals. The figure illustrates the acoustic signal diagrams of different frequencies received by different subjects.

Referring to FIGS. 4B and 4C together, they illustrate the physical change information of the subject A (vertical direction/horizontal direction) according to an embodiment of the present invention. As shown in the figures, the left side of FIG. 4B indicates that the subject A moves in the vertical direction relative to the image capturing device, while the right side shows the corresponding amplitude intensity variation curve. The X-axis represents time, and the Y-axis represents the amplitude value obtained after Fourier transformation (i.e., the intensity of the received acoustic signal). Here, a higher amplitude value indicates that the subject A is closer to the image capturing device, while a lower amplitude value indicates that the subject A is farther away from the image capturing device. Similarly, the left side of FIG. 4C indicates that the subject A moves in the horizontal direction relative to the image capturing device, and the right side shows the corresponding intensity variation curve. The X-axis represents time, and the Y-axis represents the amplitude value obtained after Fourier transformation (i.e., the intensity of the received acoustic signal). Likewise, a higher amplitude value indicates that the subject A is closer to the image capturing device, while a lower amplitude value indicates that the subject A is farther away. Thus, it can be determined whether the subject A is located on the left or right side of the image capturing device in the horizontal direction. The implementation of subject B is the same as that of subject A, with the only difference being the acoustic frequency, so it will not be elaborated further here.

In summary, the present invention provides an acoustic annotation training method, system, and device applied to physical change phenomena, which uses acoustic signals for user dynamic behavior analysis, thereby improving the precision of behavior analysis, enhances the user's listening experience, addressing the limitations of conventional positioning technologies and achieving the objectives of the present invention.

The above description is only a preferred embodiment of the present invention and should not be construed as limiting the scope of the invention. Therefore, any simple equivalent modifications and variations made based on the patent claims and the content of the specification of the present invention shall still fall within the scope of the patent of the present invention.

What is claimed is:

1. An acoustic annotation training method applied to physical change phenomena, comprising:
capturing a physical change phenomenon by an acquisition unit;
generating and transmitting a corresponding acoustic signal based on the physical change phenomenon by a transmitting portion;
receiving and performing computational analysis based on changes in the acoustic signal, and generating a corresponding physical change information by a receiving portion; and
receiving and annotating the physical change phenomenon based on the physical change information to perform multimodal computational analysis, and generating an analysis result by a computing processing unit.

2. The acoustic annotation training method applied to physical change phenomena according to claim 1, wherein in a step of performing multimodal computation analysis by the computing processing unit to generate the analysis result based on the physical change information, the computing processing unit receives and processes the physical change information to generate a corresponding semantic information, thereby enabling the computing processing unit to annotate the physical change phenomenon based on the semantic information.

3. The acoustic annotation training method applied to physical change phenomena according to claim 1, wherein an acquired form of the physical change phenomenon is selected from detected electronic signals, images, audio, voice, text, or any combination of two or more thereof.

4. The acoustic annotation training method applied to physical change phenomena according to claim 3, wherein, when the acquired form of the physical change phenomenon is an image, the method further comprises steps of:
acquiring an image information by the acquisition unit, wherein the image information includes the physical change phenomenon;
generating and transmitting the corresponding acoustic signal based on the physical change phenomenon by the transmitting portion;
receiving and performing computational analysis based on the changes in physical change information, generating a corresponding physical change information by the receiving portion; and
receiving and annotating the image information based on the physical change information to perform multimodal computational analysis, and generating the analysis result by the computing processing unit.

5. The acoustic annotation training method applied to physical change phenomena according to claim 4, wherein, in the step of receiving and annotating the image information based on the physical change information to perform multimodal computational analysis, and generating the analysis result by the computing processing unit, the computing processing unit receives and processes the physical change information to generate a corresponding semantic information, thereby enabling the computing processing unit to annotate the image information based on the semantic information.

6. The acoustic annotation training method applied to physical change phenomena according to claim 1, wherein the physical change phenomenon is selected from spatial position change, temperature change, elastic change, electromagnetic change, light change, wave change, vibration change, mass change, airflow rate change, humidity change, or any combination of two or more thereof.

7. The acoustic annotation training method applied to physical change phenomena according to claim 1, wherein a frequency range of the acoustic signal is selected from 20 Hz to 2 MHz.

8. An acoustic annotation training system applied to physical change phenomena, comprising:
an acquisition unit for acquiring a physical change phenomenon;
a conversion unit, comprising a transmitting portion and a receiving portion, wherein the transmitting portion is configured to generate and transmit a corresponding acoustic signal based on the physical change phenomenon, and the receiving portion is configured to receive and perform computational analysis based on changes in the acoustic signal, and generating a corresponding physical change information; and
a computing processing unit, respectively signal-connected to the acquisition unit and the conversion unit, being configured to receive and annotate the physical change phenomenon based on the physical change information, and to perform multimodal computational analysis to generate an analysis result.

9. The acoustic annotation training system for physical change phenomena according to claim 8, wherein the acquisition unit is selected from an image capture device, a voice capture device, an input device, a sensing device, or a combination of any two or more thereof.

10. The acoustic annotation training system for physical change phenomena according to claim 9, wherein, when the acquisition unit is the image capturing device, the acquisition unit captures an image information and obtains the physical change phenomenon from the image information.

11. The acoustic annotation training system for physical change phenomena according to claim 8, wherein the computing processing unit includes a semantic conversion unit configured to receive and perform a computing processing based on the physical change information to generate a corresponding semantic information, thereby enabling the computing processing unit to receive and annotate the physical change phenomenon based on the semantic information and execute multimodal computational analysis to produce the analysis result.

12. The acoustic annotation training system for physical change phenomena according to claim 8, wherein the physical change phenomenon is selected from spatial position change, temperature change, elastic change, electromagnetic change, light change, wave change, vibration change, mass change, airflow rate change, humidity change, or any combination of two or more thereof.

13. The acoustic annotation training system for physical change phenomena according to claim 8, wherein the frequency range of the acoustic signal is selected from 20 Hz to 2 MHz.

14. An acoustic annotation training device applied to physical change phenomena, comprising:
a detection device for generating and transmitting an acoustic signal based on a physical change phenomenon; and
a computing device, signal-connected to the detection device, being configured to receive and perform a computational analysis based on changes in the acoustic signal, and generate a corresponding physical change information, thereby annotating the physical change phenomenon based on the physical change information to execute multimodal computational analysis, and produce an analysis result.

15. The acoustic annotation training device for physical change phenomena according to claim 14, wherein the detection device includes a sensing device for detecting the physical change phenomenon, generating the physical change information, and enabling the detection device to generate and emit the acoustic signal based on the physical change information.

16. The acoustic annotation training device for physical change phenomena according to claim 14, wherein a form of the physical change phenomenon acquired by the detection device is selected from detected electronic signals, images, audio-visual data, voice, text, or any combination of two or more thereof.

17. The acoustic annotation training device for physical change phenomena according to claim 14, comprising:
a decision-making device, signal-connected to the computing device, being configured to receive the analysis result and conduct a prediction based thereon, and output a decision-making information; and
an automation device, signal-connected to the decision-making device, being configured to operate based on the decision.

18. The acoustic annotation training device for physical change phenomena according to claim 17, wherein the automation device is selected from a robotic arm, a self-propelled device, a drone, or a robot.

19. The acoustic wave annotation training device for physical change phenomena according to claim 14, wherein the physical change phenomenon is selected from spatial position change, temperature change, elastic change, electromagnetic change, light change, wave change, vibration change, mass change, airflow rate change, humidity change, or any combination of two or more thereof.

20. The acoustic annotation training device for physical change phenomena according to claim 14, wherein the frequency range of the acoustic signal is selected from 20 Hz to 2 MHz.
